(19) United States
(12) Patent Application Publication
(10) Pub. No.: US 2020/0296272 A1
(43) Pub. Date: Sep. 17, 2020

(54) SYSTEMS AND METHODS OF DISSIPATING HEAT FROM AN ELECTRONIC COMPONENT

(71) Applicant: Smart Supervision System LLC, Samara (RU)

(72) Inventor: Anton Kramarov, Samara (RU)

(73) Assignee: Smart Supervision System LLC, Samara (RU)

(21) Appl. No.: 16/816,090

(22) Filed: Mar. 11, 2020

Related U.S. Application Data
(60) Provisional application No. 62/817,751, filed on Mar. 13, 2019.

(51) Int. Cl. H04N 5/225; H05K 7/20

(52) U.S. Cl. CPC H04N 5/22521; H05K 7/20318

(57) ABSTRACT

Systems and methods of dissipating heat from an electronic component in a camera system are provided. In one exemplary embodiment, a heat transfer mechanism is configured to cool a camera system having electronic components including an optical sensor, a processor and a neural processing unit (NPU). The heat transfer mechanism comprises an evaporator structure having a heat transfer agent in liquid form disposed therein. Further, the electronic components are thermally coupled to one or more longitudinal sides of the evaporator structure. The evaporator structure is operable to generate vapor from a portion of the heat transfer agent in liquid form responsive to absorbing heat from at least one of the electronic components. The generated vapor enables circulation of the heat transfer agent in liquid form through the heat transfer system so that the absorbed heat can be dissipated to a medium surrounding the camera system.

### CROSS REFERENCE TO RELATED APPLICATIONS

This application claims the benefit of U.S. Prov. App. No. 62/817,751, filed Mar. 13, 2019, which is hereby incorporated by reference as if fully set forth herein.

### FIELD OF DISCLOSURE

The present invention relates generally to cooling systems and in particular to dissipating heat from an electronic component in a camera system.

### BACKGROUND

Modern image and video surveillance systems require more computing power to implement various algorithms and functions, which leads to an increase in heat generation due to the additional computing power. An active cooling system, where a radiator and a cooler are used to dissipate heat from an electronic component (e.g., microprocessor, central processing unit (CPU) or the like) and a perforated and not sealed body is made to provide convective air flow. This cooling system requires additional electrical power and typically cannot be installed outdoors due to environmental influences such as rain, moisture, fog, particulate matter such as dust, rodents, insects, and the like.

Many thermal strategies have been tried to dissipate heat from electronic components so as to cool them. Many systems or devices that incorporate electronic components use a heat sink to absorb and dissipate heat from the electronic components. A heat sink is a component or assembly that transfers heat from a higher temperature medium to a lower temperature medium. Although the lower temperature medium may be a fluid, the lower temperature medium is typically air.

While a larger heat sink with more surface area dissipates more heat to the ambient atmosphere, there is often a tension or trade-off between the size and effectiveness of the heat sink versus the commercially viable size of the device that must incorporate the heat sink. For instance, a video camera may require a smaller-sized heat sink to remain unobtrusive in an environment monitored by that camera. To improve thermal performance in some applications, an active cooling element may be used to dissipate heat from a heat sink or from another thermal element that absorbs heat from the electronic component. Examples of active cooling elements include fans, Peltier devices, membrane cooling elements, and the like.

Other thermal strategies for equipment that use an electronic component have utilized heat pipes or other devices that operate based on principles of thermal conductivity and phase transition. For instance, a heat pipe may be used alone or in combination with a heat sink or an active cooling element. A heat pipe relies on thermal conductivity and transition between evaporation and condensation to transfer heat to an external medium (e.g., air). Such a device includes a vapor chamber and a heat transfer agent within the chamber, typically at a pressure somewhat lower than atmospheric pressure. The heat transfer agent, in its liquid state, contacts the hot interface of the chamber where the agent absorbs heat sufficient to convert the agent to a vapor. The vapor fills the non-liquid volume of the chamber where the vapor condenses back to its liquid state at the cold interface corresponding to the cooler walls of the chamber. The thermal conductivity at this cold interface allows heat transfer away from the electronic component to, for instance, a heat sink or ambient air. By gravity or a wicking structure, the liquid form of the fluid flows back to the hot interface where it re-undergoes evaporation. As such, the heat transfer agent continues through this evaporation, condensation, and return flow to form a repeating thermal cycle that effectively transfers heat from the hot interface to the cold interface. Heat pipes can be more effective than passive elements like heat sinks. Further, heat pipes do not require electrical power or mechanical parts as needed for active cooling elements. As one example of a heat pipe, U.S. Pat. No. 4,467,861 discloses a loop heat pipe, the disclosure of which is incorporated herein by reference.

Although these prior technologies address thermal issues associated with electronic components, the structures and implementations for heat dissipation may be tailored for specific applications. Accordingly, there is a need for improved techniques for dissipating heat of electronic components in a camera system. In addition, other desirable features and characteristics of the present disclosure will become apparent from the subsequent detailed description and embodiments, taken in conjunction with the accompanying figures and the foregoing technical field and background.

The Background section of this document is provided to place embodiments of the present disclosure in technological and operational context, to assist those of skill in the art in understanding their scope and utility. Unless explicitly identified as such, no statement herein is admitted to be prior art merely by its inclusion in the Background section.

### SUMMARY

The following presents a simplified summary of the disclosure in order to provide a basic understanding to those of skill in the art. This summary is not an extensive overview of the disclosure and is not intended to identify key/critical elements of embodiments of the disclosure or to delineate the scope of the disclosure. The sole purpose of this summary is to present some concepts disclosed herein in a simplified form as a prelude to the more detailed description that is presented later.

Briefly described, embodiment of the present disclosure relate to systems and methods of dissipating heat from an electronic component in a camera system. According to one aspect, a heat transfer mechanism is configured to cool a camera system that autonomously detects and identifies objects (e.g., retail items) proximate the camera system, the camera system having electronic components including an optical sensor (e.g., image sensor, infrared sensor, or the like), a processor (e.g., CPU), and a neural processing unit (NPU). Further, the heat transfer mechanism and the electronic components are disposed in a sealed and environmentally protected housing (e.g., metallic housing) of the camera system. The heat transfer system comprises an evaporator structure having a heat transfer agent in liquid form (e.g., water, coolant) disposed therein. Further, a plurality of electronic components, including the processor and the NPU that are collectively configured to detect and identify objects from images captured by the optical sensor, is thermally coupled to one or more longitudinal sides of the evaporator structure. The evaporator structure is operable to generate vapor from a portion of the heat transfer agent in liquid form responsive to absorbing heat from at least one of the electronic components. Also, the generated vapor enables circulation of the heat transfer agent in liquid form through the heat transfer system so that at least a portion of the absorbed heat can be dissipated by the housing that is thermally coupled to the heat transfer mechanism, to a medium (e.g., air) surrounding the camera system.

According to another aspect, the heat transfer mechanism further includes a vapor jet pump operationally coupled to the evaporator structure and operable to transform vapor back to liquid form so as to induce circulation of the heat transfer agent in liquid form through the heat transfer mechanism.

According to another aspect, the heat transfer mechanism further includes a heat exchanger operationally coupled to the evaporator structure and operable to dissipate heat from the heat transfer agent in liquid form into a medium surrounding the heat transfer mechanism.

According to another aspect, the heat exchanger is thermally coupled to a housing having the heat transfer mechanism and the electronic components disposed therein.

According to another aspect, the heat transfer mechanism further includes a conduit that is operationally coupled between the heat exchanger and the evaporator structure. Further, the conduit is thermally coupled to the housing.

According to another aspect, at least a portion of the conduit is disposed in the housing.

According to another aspect, one longitudinal side of the evaporator structure is thermally coupled to an electronic component and an opposite longitudinal side of the evaporator structure is thermally coupled to another electronic component.

According to another aspect, one longitudinal side of the evaporator structure is thermally coupled to at least one electronic component affixed to a first printed circuit board (PCB) and an opposite longitudinal side of the evaporator structure is thermally coupled to at least one electronic component affixed to a second PCB.

According to another aspect, a same longitudinal side of the evaporator structure is thermally coupled to at least two of the electronic components.

According to another aspect, a thermal interface material is disposed between each electronic component and a different surface of the evaporator structure.

According to another aspect, a thermal interface material is disposed between at least two of the electronic components on a same longitudinal side of the evaporator structure. Further, each electronic component has a different gap between that electronic component and that same side.

According to one aspect, a camera system is configured to autonomously detect and identify objects proximate the camera system and comprises a plurality of electronic components including an optical sensor, a processor and an NPU. The processor and the NPU are collectively configured to detect and identify objects from images captured by the optical sensor. The system further comprises a heat transfer mechanism that includes an evaporator structure having a heat transfer agent in liquid form disposed therein. At least two of the electronic components, including the processor and the NPU, are thermally coupled to one or more longitudinal sides of the evaporator structure. Also, the evaporator structure is operable to generate vapor from a portion of the heat transfer agent in liquid form responsive to absorbing heat from at least one of the electronic components. The generated vapor enables circulation of the heat transfer agent in liquid form through the heat transfer system so that heat from the heat transfer agent in liquid form can be dissipated to a medium surrounding the heat transfer mechanism. In addition, a sealed and environmentally protected housing is thermally coupled to the heat transfer mechanism and has the heat transfer mechanism and the electronic components disposed therein. The housing is configured to dissipate heat absorbed from the heat transfer mechanism to a medium surrounding the camera system.

According to another aspect, the system further comprises one or more PCBs with each PCB having at least one electronic component affixed thereon. Further, each PCB is planar to a different side of the evaporator structure.

According to another aspect, the heat transfer mechanism further includes a heat exchanger that is operable to dissipate heat from the heat transfer agent in liquid form to the surrounding medium. The heat transfer mechanism also includes a conduit that is operationally coupled between the heat exchanger and the evaporator structure. In addition, the conduit is thermally coupled to the housing.

According to another aspect, at least a portion of the conduit is disposed in the housing.

According to another aspect, one side of the evaporator structure is thermally coupled to one electronic component and an opposite side of the evaporator structure is thermally coupled to a different electronic component.

According to another aspect, a thermal interface material is disposed between at least two of the electronic components that are thermally coupled on a same longitudinal side of the evaporator structure. Further, each electronic component has a different gap between that electronic component and that same side.

According to one aspect, a heat transfer mechanism is configured to cool a camera system that autonomously detects and identifies objects proximate the camera system. Further, the camera system has electronic components including an optical sensor, a processor and an NPU. The heat transfer mechanism and the electronic components are disposed in a sealed and environmentally protected housing of the camera system. The heat transfer mechanism comprises a contact region thermally coupled to the body and operable to absorb heat from a plurality of the electronic components, including the processor and the NPU that are collectively configured to detect and identify objects from images captured by the optical sensor. Each electronic component is thermally coupled to a different surface area of the contact region. Further, each electronic component and a corresponding surface of the contact region may have a different gap with a thermal interface material disposed in that gap. The heat transfer mechanism further includes a body operable to transfer heat through the heat transfer mechanism. The body may be coupled to the housing having the contact region and the electronic components disposed therein. In addition, the heat transfer mechanism includes a wicking structure having a plurality of heat dissipating fins with adjacent fins defining channels between them. The wicking structure is operable to dissipate heat absorbed by the contact region from the electronic components and transferred to the wicking structure by the body to a medium surrounding the fins. Each fin has bottom and end portions. The end portion of each fin may have a curvilinear geometric shape such as a cylindrical shape. Also, each channel at the base portions of adjacent fins may have a curvilinear geometric shape. Moreover, a width of each fin may be tapered from the base portion to the end portion of that fin.

According to one aspect, a camera system is configured to autonomously detect and identify objects proximate the camera system and comprises a heat transfer system, a sealed and environmentally protected housing, and a plurality of electronic components including an optical sensor, a processor and an NPU. The processor and the NPU are collectively configured to detect and identify objects from images captured by the optical sensor. The heat transfer mechanism includes a contact region operable to absorb heat from a plurality of electronic components with each electronic component being thermally coupled to a different surface area of the contact region. Further, each electronic component and a corresponding surface of the contact region may have a different gap with a thermal interface material disposed in that gap. The heat transfer mechanism further includes a body thermally coupled to the contact region and operable to transfer heat through the heat transfer mechanism. The heat transfer mechanism also includes a wicking structure thermally coupled to the body and having a plurality of heat dissipating fins with adjacent fins defining channels between them. The wicking structure is operable to dissipate heat absorbed by the contact region and transferred to the wicking structure by the body to a medium surrounding the fins. Each fin has bottom and end portions. The end portion of each fin may have a curvilinear geometric shape such as a cylindrical shape. Also, each channel at the base portions of adjacent fins may have a curvilinear geometric shape. Moreover, a width of each fin may be tapered from the base portion to the end portion of that fin. In addition, a sealed and environmentally protected housing may be coupled to the body and may have the heat transfer mechanism and the electronic components disposed therein.

According to another aspect, the camera system further includes a PCB having a plurality of electronic component affixed thereon. Further, the PCB is planar to the contact region, the base and the wicking structure of the heat transfer mechanism.

### BRIEF DESCRIPTION OF THE DRAWINGS

The present disclosure will now be described more fully hereinafter with reference to the accompanying drawings, in which embodiments of the disclosure are shown. However, this disclosure should not be construed as limited to the embodiments set forth herein. Rather, these embodiments are provided so that this disclosure will be thorough and complete, and will fully convey the scope of the disclosure to those skilled in the art. Like numbers refer to like elements throughout.

FIG. 1 illustrates one embodiment of a camera system having a heat transfer mechanism in accordance with various aspects as described herein.

FIG. 2 illustrates one embodiment of a heat transfer mechanism in accordance with various aspects as described herein.

FIG. 3 illustrates another embodiment of a camera system having a heat transfer mechanism in accordance with various aspects as described herein.

FIG. 4 illustrates another embodiment of a camera system having a heat transfer mechanism in accordance with various aspects as described herein.

FIG. 5 illustrates another camera system in accordance with various aspects as described herein.

### DETAILED DESCRIPTION

For simplicity and illustrative purposes, the present disclosure is described by referring mainly to an exemplary embodiment thereof. In the following description, numerous specific details are set forth in order to provide a thorough understanding of the present disclosure. However, it will be readily apparent to one of ordinary skill in the art that the present disclosure may be practiced without limitation to these specific details.

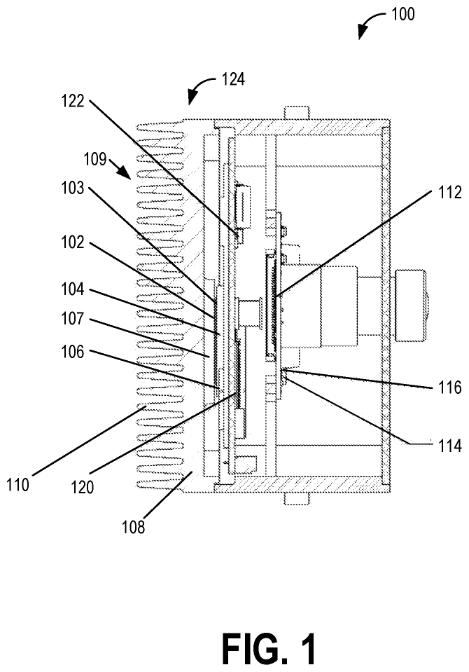

This disclosure describes systems and methods of dissipating heat from an electronic component of a camera system, including dissipating heat from electronic components such as a processor, memory, and an NPU of a fully or partially enclosed camera system. For example, FIG. 1 illustrates one embodiment of a camera system 100 having a heat transfer mechanism 124 in accordance with various aspects as described herein. In FIG. 1, the system 100 may include electronic components such as: a processor 102 (e.g., CPU); a random access memory (RAM) 104; a flash memory 106; an NPU 103; an optical sensor 112 such as used in a camera; a three-axis compass, global positioning system (GPS), or the like 114; an accelerometer, gyroscope, magnetometer, or the like 116; a wireless communications module 120 (e.g., Wi-Fi module, Bluetooth module, or the like); a radio frequency (RF) transceiver module 122; the like; or any combination thereof. In one example, the optical sensor 112 is a complementary metal oxide semiconductor (CMOS) image sensor that is operable to capture images and video. In one definition, an NPU is a specialized circuit (e.g., discrete logic, field programmable gate array (FPGA), application specific integrated circuit (ASIC), or the like) that implements control and arithmetic logic to perform machine learning or artificial intelligence (Al) algorithms that operate on predictive models such as artificial neural networks. In another definition, an NPU is a specialized circuit that increases the efficiency of performing machine learning or Al algorithms over a general purpose processor such as a central processing unit (CPU). An NPU may be a tensor processing unit (TPU), a neural network processor (NNP), an intelligence processing unit (IPU), a vision processing unit (VPU), a graphical processing unit (GPU), the like, or any combination thereof. The heat transfer mechanism 124 may be capable of thermal conductivity or phase transitions. Further, the heat transfer mechanism 124 may be configured to passively cool one or more of the electronic components of the system 100. In one example, the heat transfer mechanism 124 is configured to passively cool the processor 102, the NPU 103, and the RAM 104.

In FIG. 1, the processor 102 may be configured so that the system 100 may perform various processing functions without a need to share information with a local/remote server or other centralized processing device. For example, the processor 102 may be configured to process one or more images captured by the image sensor 112 and perform object detection on such processed images. In addition, the processor 102 may be configured to perform various processing functions on behalf of other camera-based systems or may utilize other camera-based systems to perform various processing functions. As such, the system 100 is configured to perform computationally-intensive, real-time or pseudo-real time processing of images or video, resulting in significant heat generation by those electronic components performing such functions. Further, the system 100 may be fully or partially enclosed or otherwise sealed to allow for prolonged continuous operation without degradation from environmental influences. However, a sealed or enclosed housing containing the electronic components will exacerbate the ability to dissipate heat from these components. Under these conditions, the heat transfer mechanism 124 is applied to adequately dissipate heat generation from these components.

In the current embodiment, the heat transfer system 124 includes a contact region 107, a body 108, a wicking structure 109 having a plurality of heat dissipating fins 110. The contact region 107 is configured to be thermally coupled to one or more electronic components. A thermal interface material (e.g., thermal grease, heat paste, heat sink compound, or the like) may be disposed between the surface of the contact region 107 and each electronic component. Further, the gaps between the surface of the contact region 107 and each electronic component may be different, requiring the thermal interface material to be disposed in these gaps such that no other medium (e.g., air) other than the thermal interface material is disposed between that surface and each electronic component.

In operation, the heat transfer process involves the transfer of heat from one or more heat sources (e.g., the processor 102, the NPU 103 and the RAM 104) to the contact region 107, which is thermally coupled to each heat source. The heat absorbed by the contact region 107 conducts through the body 108 of the heat transfer mechanism 124 to the wicking structure 109 where the absorbed heat is dissipated to the medium (e.g., air) surrounding each fin 110. The fins 110 are configured to increase the total surface area of the wicking structure 109 so as to increase the overall heat transfer by convection. Prior art fin designs typically employ parallel fins with rectangular channels between adjacent fins. However, the rectangular channels block and obstruct the flow of a surrounding medium (e.g., air), resulting in increased flow resistance, lower flow velocity and reduced convective cooling. In addition, the rectangular channels project radiating heat towards adjacent fins, resulting in partially heating the adjacent fins. To reduce these effects, the end portion of each fin 110 may be configured to have a curvilinear geometric shape such as a cylindrical shape. The channels between adjacent fins 110 may also be configured to have a curvilinear geometric shape. Further, the width of each fin 110 may be tapered from the base portion to the end portion of each fin 110. In one example, the taper angle is in a range between about one degree (1°) and ten degrees (10°). In another example, the taper angle is about three degrees (3°).

The amount of heat transferred is determined by the basic heat transfer equation. For steady-state, Equation (1) represents the basic heat transfer equation.

Q=KA(t₂−t₁) (1)

where Q is heat flux, K is thermal conductivity, A is area, t₂ is ambient temperature, t₁ is the heat source (e.g., electronic component) temperature. Considering that a heat conductive area may not change due to construction constraints, the only optimization may be thermal conductivity as well as a difference between ambient temperature and heat source temperature. Thermal conductivity is the inverse of thermal resistance. Thermal resistance may be decreased in various ways. For example, a contact area between a case and an environment may be increased by designing a ribbed case such as a typical radiator. Furthermore, the area disposed between any of the electronic components (e.g., the processor 102) and the contact area 107 of the heat transfer mechanism 124 may not be smooth and even so a thermally conductive paste may be used to increase the thermal coupling between the electronic components and the contact area 107.

In another embodiment, a loop heat pipe (LHP) structure may be used to increase the speed of heat transfer from the electronic components (e.g., processor 102) to a surrounding medium of the system 100. The LHP technology may allow the use of a passive cooling system in a sealed and environmentally protected housing as well as may decrease the power consumption and size of the system 100. The LHP structure includes a vapor tight chamber and a heat transfer agent disposed in that chamber. In operation, the pressure in the chamber causes the heat transfer agent to absorb heat from the electronic component, then the fluid vaporizes at a relatively warmer location of the heat transfer mechanism as the fluid absorbs heat, then the fluid transfers heat to and condenses at a relatively cooler location of the heat transfer mechanism, with the fluid finally returning as a liquid to the relatively warmer location of the heat transfer mechanism.

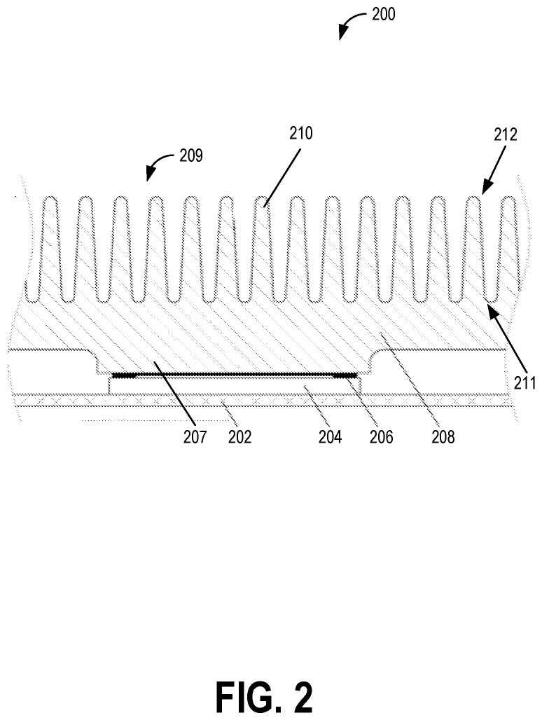

FIG. 2 illustrates one embodiment of a heat transfer mechanism 200 in accordance with various aspects as described herein. In FIG. 2, the heat transfer mechanism 200 may be utilized, for example, as part of the camera system 100 of FIG. 1. The heat transfer mechanism 200 may include a contact area 207, a body 208, and a wicking structure 209. The contact area 207 is thermally coupled to one or more electronic components 204 (e.g., processor, NPU, amplifier, transistor, resistor, another electronic component, or the like) mounted on a PCB 202. Further, thermal interface material 206 may be disposed between the contact area 207 and the electronic component 204. The thermal interface material 206 may be any material (e.g., thermal grease, thermal adhesive, thermal gap filler, or the like) that is inserted between a heat sink and a heat source to enhance the thermal coupling between them. Further, the thermal interface material may eliminate or reduce air gaps or spaces (which act as thermal insulation) from the interface area between a heat sink and a heat source in order to maximize heat transfer and dissipation.

In FIG. 2, the wicking structure 209 has a plurality of heat dissipating fins 210 with adjacent fins 210 defining channels between them. The wicking structure 209 is configured to increase the surface area of the heat transfer mechanism 200 so as to increase the time-based rate of heat dissipation from the electronic component 204. The wicking structure 209 is operable to dissipate heat absorbed from the electronic component 204 by the contact region 207 and transferred to the wicking structure 209 by the body 208 to a medium surrounding the fins 210. Each fin 210 has a bottom portion 211 and an end portion 212. The end portion 212 has a curvilinear geometric shape such as a cylindrical shape and each channel at the base portions of adjacent fins also have a curvilinear geometric shape. Moreover, a width of each fin 210 is tapered from the base portion 211 to the end portion 212 of that fin 210. In one example, the taper angle is in a range between about zero degree (0°) and twenty degrees (20°). In another example, the taper angle is about five degrees (5°).

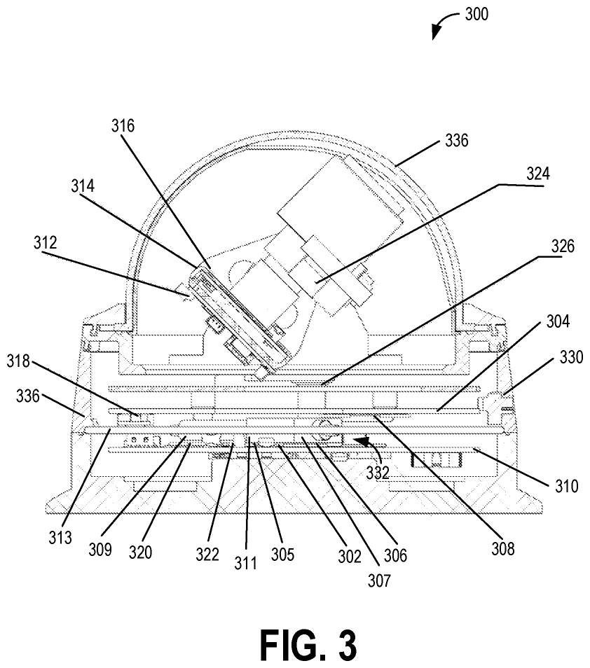

FIG. 3 illustrates another embodiment of a camera system 300 having a heat transfer mechanism 332 in accordance with various aspects as described herein. In FIG. 3, the system 300 may include electronic components such as: a processor 302 (e.g., CPU); a RAM 304; a flash memory 306; a first NPU 308; a second NPU 305; an image sensor 312 (e.g., CMOS image/video sensor); a three-axis compass, global positioning system, magnetometer, or the like 31; an accelerometer, gyroscope or the like 316; a cellular communications module 318; a Wi-Fi/Bluetooth communications module 320; an RF transceiver module 322; an audio capture module 330; the like; or any combination thereof. Further, the system 300 may include mechanical components such as a first motor/servo 324, a second motor/servo 326, a housing 336, the like, or any combination thereof. In one example, the processor 302 may be configured to control the first motor/servo 324 to adjust focus or zoom of the camera system 300 and the second motor/servo 326 may be configured to control tilt or pan of the camera system 300.

In FIG. 3, the camera system 300 may also include a heat transfer mechanism 332 configured to dissipate heat from one or more electronic components of the camera system 300 to the surrounding environment of the system 300. The heat transfer mechanism 332 may include a vapor tight, evaporating chamber 307 with a heat transfer agent in the liquid phase disposed within the chamber, a heat exchanging chamber 309, a vapor jet pump 311, a conduit 313, the like, or any combination thereof. In one example, the heat transfer mechanism 332 is configured to passively dissipate heat from the processor 302, the second NPU 305, and the FPGA 308. The heat transfer mechanism 332 may be an LHP such as that described by U.S. Pat. No. 4,467,861. In FIG. 3, the conduit 313 is operationally coupled between the heat exchanger 309 and the evaporator structure 307. Further, the conduit 313 may be thermally coupled to the housing 336. In one example, at least a portion of the conduit 313 is disposed in the housing 336. In addition, the heat transfer mechanism 332 and the electronic components may be disposed in a sealed and environmentally protected housing 336.

In another embodiment, the processor 302, the first NPU 308, the second NPU 305, the like, or any combination thereof may be collectively configured to perform various processing functions without the need of the camera system 300 to share information with a local/remote server or another camera system. For example, the processor 302, the first NPU 308, the second NPU 305, the like, or any combination thereof may be individually or collectively configured to receive and process one or more images captured by the image sensor 312 and then perform image-related functions such as object detection, identification, or classification. In addition, the processor 302, the first NPU 308, the second NPU 305, the like, or any combination thereof may be individually or collectively configured to perform various processing functions on behalf of other camera systems and/or utilize other cameras to perform various processing functions.

In another embodiment, the camera system 300 may be fully or partially enclosed or otherwise sealed. For example, the camera system 300 may be operated in an outdoor environment or in an otherwise harsh or dirty environment without the internal components of the camera system 300 being exposed to particulate matter from the surrounding environment. The increased processing functionality of the processor 302 in these environments may lead to increased heat generation. Further, the enclosed or sealed camera system 300 may limit the ability to dissipate this heat.

In another embodiment, one longitudinal side of the evaporator structure 307 is thermally coupled to one electronic component such as the the first NPU 308 and an opposite longitudinal side of the evaporator structure 307 is thermally coupled to another electronic component such as the processor 302.

In another embodiment, one longitudinal side of the evaporator structure 307 is thermally coupled to at least one electronic component affixed to a first PCB 304 and an opposite longitudinal side of the evaporator structure is thermally coupled to at least one electronic component affixed to a second PCB 310.

In another embodiment, the heat transfer mechanism 332 and the electronic components are disposed in a sealed and environmentally protected housing 336.

In another embodiment, the same longitudinal side of the evaporator structure 307 is thermally coupled to at least two of the electronic components such as the processor 302 and the second NPU 305.

In another embodiment, the same longitudinal side of the evaporator structure 307 is thermally coupled to at least two of the electronic components such as the processor 302 and the second NPU 305, and a different longitudinal side of the evaporator structure 307 is thermally coupled to the first NPU 308.

In another embodiment, a thermal interface material is disposed between each electronic component (e.g., the processor 302 and the flash memory 306) and a different surface of the evaporator structure 307.

In another embodiment, a thermal interface material is disposed between at least two of the electronic components on a same longitudinal side of the evaporator structure (e.g., the processor 302 and the flash memory 306), with each electronic component having a different gap between that electronic component and that same side.

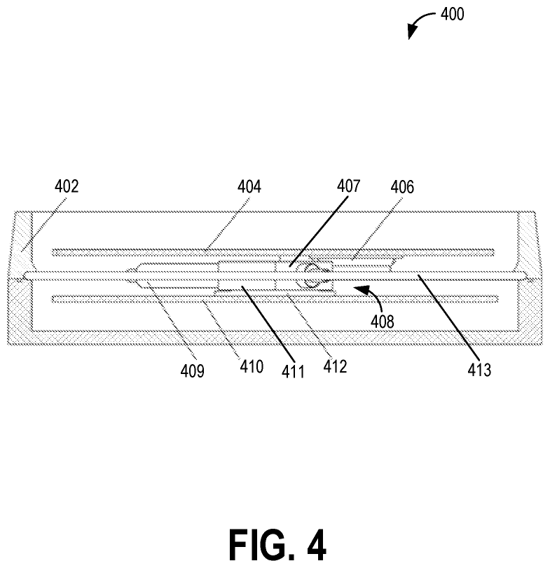

FIG. 4 illustrates one embodiment of a heat dissipation system 400 having a heat transfer mechanism 408 in accordance with various aspects as described herein. The heat transfer mechanism 408 may be utilized, for example, as part of the camera system 100 of FIG. 1 and the camera system 300 of FIG. 3. In FIG. 4, an electronic component 406 (e.g., NPU) may be mounted on a PCB 404 and another electronic component 412 (e.g., CPU) may be mounted on another PCB 410. In addition, the heat transfer mechanism 408 may be disposed between both electronic components 406, 412. In one example, the heat transfer mechanism 408 is a loop heat pipe such as that described by U.S. Pat. No. 4,467,861. In addition, the electronic components 406, 412, the PCBs 404, 410, and the heat transfer mechanism 408 may be disposed in a metal casing or housing 402.

In FIG. 4, the heat transfer mechanism 408 includes a vapor tight, evaporating chamber 407 with a heat transfer agent in the liquid phase disposed within the chamber, a heat exchanging chamber 409, a vapor jet pump 411, and a conduit 413. The heat transfer agent is applied to reduce or regulate the temperature of a system and may be air, hydrogen, helium, water, refrigerant, oil, the like, or any combination thereof. Further, the heat transfer agent may have one or more characteristics such as high thermal capacity, low viscosity, low cost, non-toxic, chemically inert, non-corrosive, and the like. In operation, the heat transfer agent in liquid form disposed in the evaporating chamber 407 begins evaporating as it absorbs heat from at least one of the electronic components 406, 412, with the resulting vapor being issued from the vapor jet pump 411 and condensing on contact with the heat transfer agent in liquid form. This evaporation and condensation process causes the dynamic pressure of the vapor to be transformed into static pressure of the liquid resulting in a pump effect that induces the circulation of the heat transfer agent in liquid form through the heat transfer mechanism 408. The condensed fluid then flows through the heat exchanging chamber 409 where the condensed fluid dissipates some of its heat to the surrounding medium, which is then dissipated to the surrounding air via the metal casing 402. Finally, the cooled condensed fluid returns to the evaporating chamber 407 via the conduit 413.

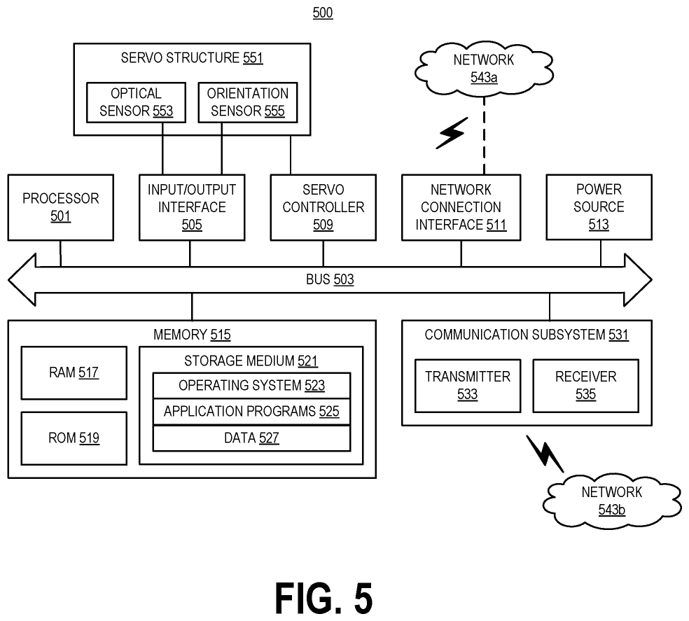

FIG. 5 illustrates another camera system 500 in accordance with various aspects as described herein. The system 500 may include all or any portion of other systems described herein. In FIG. 5, the system 500 includes a servo structure 551 that is configured to orient an optical sensor 553 (e.g., camera) such as towards an object. In addition to the optical sensor 553, the servo structure 551 also includes an orientation sensor 555 (e.g., accelerometer, gyroscope, magnetometer, compass, the like, or any combination thereof) that is configured to measure the orientation or location of the optical sensor 553. Further, the system 500 includes processing circuitry 501 that is operatively coupled to input/output interface 505, a servo controller 509, network connection interface 511, memory 515 including random access memory (RAM) 517, read-only memory (ROM) 519, and storage medium 521 or the like, communication subsystem 531, power source 513, and/or any other component, or any combination thereof. The storage medium 521 includes an operating system 523, one or more application programs 525, and data 527. In other embodiments, the storage medium 521 may include other similar types of information. Certain systems may utilize all of the components shown in FIG. 5, or only a subset of the components. The level of integration between the components may vary from one system to another system. Further, certain systems may contain multiple instances of a component, such as multiple processors, memories, neural networks, network connection interfaces, transceivers, etc.

In FIG. 5, the processing circuitry 501 may be configured to process computer instructions and data. The processing circuitry 501 may be configured to implement any sequential state machine operative to execute machine instructions stored as machine-readable computer programs in the memory, such as one or more hardware-implemented state machines (e.g., in discrete logic, FPGA, ASIC, etc.); programmable logic together with appropriate firmware; one or more stored program, general-purpose processors, such as a microprocessor or digital signal processor (DSP), together with appropriate software; or any combination of the above. For example, the processing circuitry 501 may include two central processing units (CPUs). Data may be information in a form suitable for use by a computer.

In the depicted embodiment, the input/output interface 505 may be configured to provide a communication interface to an input device, output device, or input and output device. The system 500 may be configured to use an output device via input/output interface 505. An output device may use the same type of interface port as an input device. For example, a USB port may be used to provide input to and output from the system 500. The output device may be a speaker, a sound card, a video card, a display, a monitor, a printer, an actuator, an emitter, a smartcard, another output device, or any combination thereof. The system 500 may be configured to use an input device via input/output interface 505 to allow a user to capture information into the system 500. The input device may include a touch-sensitive or presence-sensitive display, an optical sensor (e.g., a digital camera, a digital video camera, a web camera, an infrared sensor, etc.), an orientation sensor (e.g., accelerometer, gyroscope, magnetometer, compass, or the like), another sensor, a microphone, a mouse, a trackball, a directional pad, a trackpad, a scroll wheel, a smartcard, and the like. The presence-sensitive display may include a capacitive or resistive touch sensor to sense input from a user. The other sensor may be, for instance, an accelerometer, a gyroscope, a tilt sensor, a force sensor, a magnetometer, an optical sensor, an infrared sensor, a proximity sensor, another like sensor, or any combination thereof.

In FIG. 5, the servo controller 509 may be configured to control one or more servos of the servo structure 551 so as to control an orientation of the optical sensor 553. The servo controller 509 may be configured to send to each servo of the servo structure 551 a signal (e.g., pulse-width modulation signal) to control the position of that server. In one example, the servo structure 551 includes two servos with a first servo to control the pitch of the optical sensor 553 and a second servo to control the yaw of the optical sensor 553. The network connection interface 511 may be configured to provide a communication interface to network 543a. The network 543a may encompass wired and/or wireless networks such as a local-area network (LAN), a wide-area network (WAN), a computer network, a wireless network, a telecommunications network, another like network or any combination thereof. For example, network 543a may comprise a Wi-Fi network. The network connection interface 511 may be configured to include a receiver and a transmitter interface used to communicate with one or more other devices over a communication network according to one or more communication protocols, such as Ethernet, TCP/IP, SONET, ATM, or the like. The network connection interface 511 may implement receiver and transmitter functionality appropriate to the communication network links (e.g., optical, electronic, and the like). The transmitter and receiver functions may share circuit components, software or firmware, or alternatively may be implemented separately.

The RAM 517 may be configured to interface via a bus 503 to the processing circuitry 501 to provide storage or caching of data or computer instructions during the execution of software programs such as the operating system, application programs, and device drivers. The ROM 519 may be configured to provide computer instructions or data to processing circuitry 501. For example, the ROM 519 may be configured to store invariant low-level system code or data for basic system functions such as basic input and output (I/O), startup, or reception of keystrokes from a keyboard that are stored in a non-volatile memory. The storage medium 521 may be configured to include memory such as RAM, ROM, programmable read-only memory (PROM), erasable programmable read-only memory (EPROM), electronicly erasable programmable read-only memory (EEPROM), magnetic disks, optical disks, floppy disks, hard disks, removable cartridges, or flash drives. In one example, the storage medium 521 may be configured to include an operating system 523, an application program 525 such as an object detection, identification or classification program, a widget or gadget engine or another application, and a data file 527. The storage medium 521 may store, for use by the system 500, any of a variety of various operating systems or combinations of operating systems.

The storage medium 521 may be configured to include a number of physical drive units, such as redundant array of independent disks (RAID), floppy disk drive, flash memory, USB flash drive, external hard disk drive, thumb drive, pen drive, key drive, high-density digital versatile disc (HD-DVD) optical disc drive, internal hard disk drive, Blu-Ray optical disc drive, holographic digital data storage (HDDS) optical disc drive, external mini-dual in-line memory module (DIMM), synchronous dynamic random access memory (SDRAM), external micro-DIMM SDRAM, smartcard memory such as a subscriber identity module or a removable user identity (SIM/RUIM) module, other memory, or any combination thereof. The storage medium 521 may allow the system 500 to access computer-executable instructions, application programs or the like, stored on transitory or non-transitory memory media, to off-load data, or to upload data. An article of manufacture, such as one utilizing a communication system may be tangibly embodied in the storage medium 521, which may comprise a device readable medium.

In FIG. 5, the processing circuitry 501 may be configured to communicate with network 543b using the communication subsystem 531. The network 543a and the network 543b may be the same network or networks or different network or networks. The communication subsystem 531 may be configured to include one or more transceivers used to communicate with the network 543b. For example, the communication subsystem 531 may be configured to include one or more transceivers used to communicate with one or more remote transceivers of another system capable of wireless communication according to one or more communication protocols, such as IEEE 802.11, CDMA, WCDMA, GSM, LTE, UTRAN, WiMax, or the like. Each transceiver may include transmitter 533 and/or receiver 535 to implement transmitter or receiver functionality, respectively, appropriate to the RAN links (e.g., frequency allocations and the like). Further, transmitter 533 and receiver 535 of each transceiver may share circuit components, software or firmware, or alternatively may be implemented separately.

In the illustrated embodiment, the communication functions of the communication subsystem 531 may include data communication, voice communication, multimedia communication, short-range communications such as Bluetooth, near-field communication, location-based communication such as the use of the global positioning system (GPS) to determine a location, another like communication function, or any combination thereof. For example, the communication subsystem 531 may include cellular communication, Wi-Fi communication, Bluetooth communication, and GPS communication. Further, the communication subsystem 531 may include functions to determine the presence or proximity of a wireless device to the system 500 or any of its components such as the sensor pad 551. For example, the communication subsystem 531 may include a Bluetooth transceiver that is operable to determine the presence or proximity of a wireless device to the sensor pad 551, with the wireless device also having a Bluetooth transceiver. A skilled artisan will readily recognize various algorithms for determining the presence or proximity of a wireless device. In addition, the system 500 via the Bluetooth transceiver of the communication subsystem 531 may obtain various information from each detected Bluetooth device such as a device name, a Bluetooth address, a device type, a first detection time, a last detection time, or the like. A wireless device may be referred to as a user equipment (UE), a mobile station (MS), a terminal, a cellular phone, a cellular handset, a personal digital assistant (PDA), a smartphone, a wireless phone, an organizer, a handheld computer, a desktop computer, a laptop computer, a tablet computer, a set-top box, a television, an appliance, a game device, a medical device, a display device, a metering device, or some other like terminology. The network 543b may encompass wired and/or wireless networks such as a local-area network (LAN), a wide-area network (WAN), a computer network, a wireless network, a telecommunications network, another like network or any combination thereof. For example, the network 543b may be a cellular network, a Wi-Fi network, and/or a near-field network. The power source 513 may be configured to provide alternating current (AC) or direct current (DC) power to components of the system 500.

The features, benefits and/or functions described herein may be implemented in one of the components of the system 500 or partitioned across multiple components of the system 500. Further, the features, benefits, and/or functions described herein may be implemented in any combination of hardware, software or firmware. In one example, communication subsystem 531 may be configured to include any of the components described herein. Further, the processing circuitry 501 may be configured to communicate with any of such components over the bus 503. In another example, any of such components may be represented by program instructions stored in memory that when executed by the processing circuitry 501 perform the corresponding functions described herein. In another example, the functionality of any of such components may be partitioned between the processing circuitry 501 and the communication subsystem 531. In another example, the non-computationally intensive functions of any of such components may be implemented in software or firmware and the computationally intensive functions may be implemented in hardware.

The previous detailed description is merely illustrative in nature and is not intended to limit the present disclosure, or the application and uses of the present disclosure. Furthermore, there is no intention to be bound by any expressed or implied theory presented in the preceding field of use, background, summary, or detailed description. The present disclosure provides various examples, embodiments and the like, which may be described herein in terms of functional or logical block elements. The various aspects described herein are presented as methods, devices (or apparatus), systems, or articles of manufacture that may include a number of components, elements, members, modules, nodes, peripherals, or the like. Further, these methods, devices, systems, or articles of manufacture may include or not include additional components, elements, members, modules, nodes, peripherals, or the like.

Furthermore, the various aspects described herein may be implemented using standard programming or engineering techniques to produce software, firmware, hardware (e.g., circuits), or any combination thereof to control a computing device to implement the disclosed subject matter. It will be appreciated that some embodiments may be comprised of one or more generic or specialized processors such as microprocessors, digital signal processors, customized processors and FPGAs and unique stored program instructions (including both software and firmware) that control the one or more processors to implement, in conjunction with certain non-processor circuits, some, most, or all of the functions of the methods, devices and systems described herein. Alternatively, some or all functions could be implemented by a state machine that has no stored program instructions, or in one or more ASICs, in which each function or some combinations of certain of the functions are implemented as custom logic circuits. Of course, a combination of the two approaches may be used. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The term “article of manufacture” as used herein is intended to encompass a computer program accessible from any computing device, carrier, or media. For example, a computer-readable medium may include: a magnetic storage device such as a hard disk, a floppy disk or a magnetic strip; an optical disk such as a compact disk (CD) or digital versatile disk (DVD); a smart card; and a flash memory device such as a card, stick or key drive. Additionally, it should be appreciated that a carrier wave may be employed to carry computer-readable electronic data including those used in transmitting and receiving electronic data such as electronic mail (e-mail) or in accessing a computer network such as the Internet or a local area network (LAN). Of course, a person of ordinary skill in the art will recognize many modifications may be made to this configuration without departing from the scope or spirit of the subject matter of this disclosure.

Throughout the specification and the embodiments, the following terms take at least the meanings explicitly associated herein, unless the context clearly dictates otherwise. Relational terms such as “first” and “second,” and the like may be used solely to distinguish one entity or action from another entity or action without necessarily requiring or implying any actual such relationship or order between such entities or actions. The term “or” is intended to mean an inclusive “or” unless specified otherwise or clear from the context to be directed to an exclusive form. Further, the terms “a,” “an,” and “the” are intended to mean one or more unless specified otherwise or clear from the context to be directed to a singular form. The term “include” and its various forms are intended to mean including but not limited to. References to “one embodiment,” “an embodiment,” “example embodiment,” “various embodiments,” and other like terms indicate that the embodiments of the disclosed technology so described may include a particular function, feature, structure, or characteristic, but not every embodiment necessarily includes the particular function, feature, structure, or characteristic. Further, repeated use of the phrase “in one embodiment” does not necessarily refer to the same embodiment, although it may. The terms “substantially,” “essentially,” “approximately,” “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. A device or structure that is “configured” in a certain way is configured in at least that way, but may also be configured in ways that are not listed.

What is claimed is:

1. A heat transfer mechanism configured to cool a camera system that autonomously detects and identifies objects proximate the camera system, the camera system having electronic components including an optical sensor, a processor and a neural processing unit (NPU), with the heat transfer mechanism and the electronic components being disposed in a sealed and environmentally protected housing of the camera system, comprising:
an evaporator structure having a heat transfer agent in liquid form disposed therein, with a plurality of the electronic components, including the processor and the NPU that are collectively configured to detect and identify objects from images captured by the optical sensor, being thermally coupled to one or more longitudinal sides of the evaporator structure, wherein the evaporator structure is operable to generate vapor from a portion of the heat transfer agent in liquid form responsive to absorbing heat from at least one of the electronic components, the generated vapor enabling circulation of the heat transfer agent in liquid form through the heat transfer system so that at least a portion of the absorbed heat can be dissipated by the housing that is thermally coupled to the heat transfer mechanism to a medium surrounding the camera system.

2. The mechanism of claim 1, further comprising:
a vapor jet pump operationally coupled to the evaporator structure and operable to transform vapor back to liquid form so as to induce circulation of the heat transfer agent in liquid form through the heat transfer mechanism.

3. The mechanism of claim 1, further comprising:
a heat exchanger operationally coupled to the evaporator structure and operable to dissipate heat from the heat transfer agent in liquid form into a medium surrounding the heat transfer mechanism.

4. The mechanism of claim 3, wherein the heat exchanger is thermally coupled to a housing having the heat transfer mechanism and the electronic components disposed therein.

5. The mechanism of claim 4, further comprising:
a conduit that is operationally coupled between the heat exchanger and the evaporator structure, wherein the conduit is thermally coupled to the housing.

6. The system of claim 5, wherein at least a portion of the conduit is disposed in the housing.

7. The mechanism of claim 1, wherein one longitudinal side of the evaporator structure is thermally coupled to one electronic component and an opposite longitudinal side of the evaporator structure is thermally coupled to another electronic component.

8. The mechanism of claim 1, wherein one longitudinal side of the evaporator structure is thermally coupled to at least one electronic component affixed to a first printed circuit board (PCB) and an opposite longitudinal side of the evaporator structure is thermally coupled to at least one electronic component affixed to a second PCB.

9. The mechanism of claim 1, wherein a same longitudinal side of the evaporator structure is thermally coupled to at least two of the electronic components.

10. The mechanism of claim 1, wherein a thermal interface material is disposed between each electronic component and a different surface of the evaporator structure.

11. The mechanism of claim 10, wherein a thermal interface material is disposed between at least two of the electronic components on a same longitudinal side of the evaporator structure, with each electronic component having a different gap between that electronic component and that same side.

12. A camera system configured to autonomously detect and identify objects proximate the camera system, comprising:
a plurality of electronic components including an optical sensor, a processor and a neural processing unit (NPU), with the processor and the NPU being collectively configured to detect and identify objects from images captured by the optical sensor;
a heat transfer mechanism, including:
an evaporator structure having a heat transfer agent in liquid form disposed therein, with at least two of the electronic components including the processor and the NPU being thermally coupled to one or more longitudinal sides of the evaporator structure, wherein the evaporator structure is operable to generate vapor from a portion of the heat transfer agent in liquid form responsive to absorbing heat from at least one of the electronic components, the generated vapor enabling circulation of the heat transfer agent in liquid form through the heat transfer system so that heat from the heat transfer agent in liquid form can be dissipated to a medium surrounding the heat transfer mechanism; and
a sealed and environmentally protected housing thermally coupled to the heat transfer mechanism and having the heat transfer mechanism and the electronic components disposed therein, with the housing being configured to dissipate heat absorbed from the heat transfer mechanism to a medium surrounding the camera system.

13. The system of claim 12, further comprising:
one or more printed circuit boards (PCBs) with each PCB having at least one electronic component affixed thereon; and
wherein each PCB is planar to a different side of the evaporator structure.

14. The system of claim 12, wherein the heat transfer mechanism further includes:
a heat exchanger that is operable to dissipate heat from the heat transfer agent in liquid form to the surrounding medium; and
a conduit that is operationally coupled between the heat exchanger and the evaporator structure, wherein the conduit is thermally coupled to the housing.

15. The system of claim 14, wherein at least a portion of the conduit is disposed in the housing.

16. The system of claim 12, wherein one side of the evaporator structure is thermally coupled to one electronic component and an opposite side of the evaporator structure is thermally coupled to a different electronic component.

17. The system of claim 12, wherein a thermal interface material is disposed between at least two of the electronic components that are thermally coupled to a same longitudinal side of the evaporator structure, with each electronic component having a different gap between that electronic component and the same side.

18. A heat transfer mechanism configured to cool a camera system that autonomously detects and identifies objects proximate the camera system, the camera system having electronic components including an optical sensor, a processor and a neural processing unit (NPU), with the heat transfer mechanism and the electronic components being disposed in a sealed and environmentally protected housing of the camera system, comprising:
a contact region operable to absorb heat from a plurality of the electronic components, including the processor and the NPU that are collectively configured to detect and identify objects from images captured by the optical sensor, with each electronic component being thermally coupled to a different surface area of the contact region, wherein each electronic component and a corresponding surface of the contact region has a different gap with a thermal interface material disposed in that gap;
a body thermally coupled to the contact region and operable to transfer heat through the heat transfer mechanism, wherein the body is coupled to the housing having the contact region and the electronic components disposed therein; and
a wicking structure thermally coupled to the body and having a plurality of heat dissipating fins with adjacent fins defining channels between them, the wicking structure being operable to dissipate heat absorbed by the contact region from the electronic components and transferred to the wicking structure by the body to a medium surrounding the fins, each fin having bottom and end portions with the end portion having a curvilinear geometric shape and each channel at the base portions of adjacent fins also having a curvilinear geometric shape, with a width of each fin being tapered from the base portion to the end portion of that fin.

19. A camera system configured to autonomously detect and identify objects proximate the camera system, comprising:
a plurality of electronic components including an optical sensor, a processor and a neural processing unit (NPU), with the processor and the NPU being collectively configured to detect and identify objects from images captured by the optical sensor;
a heat transfer mechanism, including:
a contact region operable to absorb heat from at least two of the electronic components including the processor and the NPU, with each electronic component being thermally coupled to a different surface area of the contact region, wherein each electronic component and a corresponding surface of the contact region has a different gap with a thermal interface material disposed in that gap;
a body thermally coupled to the contact region and operable to transfer heat through the heat transfer mechanism; and
a wicking structure thermally coupled to the body and having a plurality of heat dissipating fins with adjacent fins defining channels between them, the wicking structure being operable to dissipate heat absorbed by the contact region and transferred to the wicking structure by the body to a medium surrounding the fins, each fin having bottom and end portions with the end portion having a curvilinear geometric shape and each channel at the base portions of adjacent fins also having a curvilinear geometric shape, with a width of each fin being tapered from the base portion to the end portion of that fin; and
a sealed and environmentally protected housing coupled to the body and having the heat transfer mechanism and the electronic components disposed therein.

20. The system of claim 19, further comprising:
a printed circuit board (PCB) having a plurality of electronic component affixed thereon; and
wherein the PCB is planar to the contact region, the base and the wicking structure.
